(19) United States
(12) Patent Application Publication
(10) Pub. No.: US 2026/0229859 A1
(43) Pub. Date: Aug. 6, 2026

(54) PROTECTOR

(71) Applicant: Sumitomo Wiring Systems, Ltd., Yokkaichi-shi (JP)

(72) Inventor: Yusuke Komatsu, Yokkaichi-shi (JP)

(73) Assignee: Sumitomo Wiring Systems, Ltd., Yokkaichi-shi (JP)

(21) Appl. No.: 19/450,203

(22) Filed: Jan. 15, 2026

(30) Foreign Application Priority Data
Jan. 31, 2025 (JP) 2025-014964

(51) Int. Cl. H02G 3/04; H02G 3/34

(52) U.S. Cl. CPC H02G 3/04; H02G 3/34

(57) ABSTRACT

A protector configured to be fixed to a fixing object by a screw, the protector including: a protector main body that is configured to hold a wire; and a screw fixing body that protrudes from the protector main body, wherein: the screw fixing body includes a screw insertion that is configured for the screw is to be inserted, and a rotation preventing portion located away from a center of the screw insertion, and the rotation preventing portion is configured to contact the fixing object to restrict rotation of the screw fixing body around the screw.

### BACKGROUND

The present disclosure relates to a protector.

JP 2021-106478A discloses a protector including: a base provided with an electric wire accommodation space on a bottom surface and an opening that opens the electric wire accommodation space on a side opposite to the bottom surface and configured to have electric wires accommodated in the electric wire accommodation space through the opening; and a cover configured to open and close the opening, wherein an insertion hole through which a rod-shaped portion of an electric wire holding jig used to hold the electric wires during assembly of a wire harness is insertable is formed through the bottom surface.

### SUMMARY

It is desired to, when a protector is fixed to a fixing object by a screw, restrict rotation of the protector around the screw.

An exemplary aspect of the disclosure provides a protector that can be restricted from rotating around a screw for fixing the protector.

A protector according to the present disclosure is a protector configured to be fixed to a fixing object by a screw, including: a protector main body configured to hold a wiring member; and a screw fixing portion protruding from the protector main body, wherein the screw fixing portion includes a screw insertion portion into which the screw is to be inserted, and a rotation preventing portion located away from a center of the screw insertion portion, and the rotation preventing portion is configured to contact the fixing object to restrict rotation of the screw fixing portion around the screw.

According to the present disclosure, a protector can be restricted from rotating around a screw for fixing the protector.

### BRIEF DESCRIPTION OF THE DRAWINGS

FIG. 1 is a perspective view showing a protector according to an embodiment;

FIG. 2 is a perspective view showing the protector according to the embodiment;

FIG. 3 is a plan view showing the protector;

FIG. 4 is a bottom view showing the protector; and

FIG. 5 is a side view showing the protector.

### DETAILED DESCRIPTION OF EMBODIMENTS

### Description of Embodiments of the Present Disclosure

First, embodiments of the present disclosure will be listed and described.

A protector according to the present disclosure is as follows.

(1) A protector is configured to be fixed to a fixing object by a screw, and includes: a protector main body configured to hold a wiring member; and a screw fixing portion protruding from the protector main body, wherein the screw fixing portion includes a screw insertion portion into which the screw is to be inserted, and a rotation preventing portion located away from a center of the screw insertion portion, and the rotation preventing portion is configured to contact the fixing object to restrict rotation of the screw fixing portion around the screw.

With this protector, the rotation preventing portion contacts the fixing object (i.e. object to be fixed), thereby restricting rotation of the screw fixing portion around the screw. Thus, rotation of the protector around the screw is restricted. Since rotation of the protector can be restricted with only one screw fixing portion, it is unnecessary to fix the protector to the fixing object at multiple locations in order to prevent rotation. This simplifies the shape of the protector.

(2) In the protector according to (1), the screw fixing portion may include a fixing piece protruding from the protector main body, and the rotation preventing portion may be a rotation preventing protrusion protruding from the fixing piece.

Thus, rotation of the protector can be prevented by forming, in the fixing object, a recess into which the rotation preventing protrusion is fitted.

(3) In the protector according to (2), the rotation preventing protrusion may include a tubular portion and a partition portion partitioning an inside of the tubular portion.

This reduces the amount of material for forming the screw fixing portion, and also contributes to robustness.

(4) In the protector according to (2) or (3), the screw insertion portion may be located at an intermediate position of the fixing piece, the fixing piece may include a plurality of rib portions extending radially around a central axis of the screw insertion portion, and at least one of the plurality of rib portions may extend to pass through the rotation preventing protrusion.

Thus, the screw insertion portion is securely supported in the fixing piece by the plurality of rib portions. In addition, since at least one of the plurality of rib portions extends so as to pass through the rotation preventing protrusion, the rotation preventing protrusion is also securely supported. As a result, the rotation preventing protrusion prevents rotation more reliably.

(5) In the protector according to any one of (2) to (4), the rotation preventing protrusion may include a guide surface that gradually tapers toward a tip.

Thus, the guide surface eases fitting of the rotation preventing protrusion into the recess of the fixing object.

(6) In the protector according to any one of (2) to (5), the rotation preventing protrusion may be located farther from the protector main body than the screw insertion portion is.

In this case, since the rotation preventing protrusion is located farther from the protector main body than the screw insertion portion is, the rotation preventing protrusion can be easily checked without being obstructed by the protector main body. Therefore, the rotation preventing protrusion can be easily inserted into the recess of the fixing object so that rotation can be restricted.

(7) In the protector according to (6), the screw insertion portion may include a screw insertion tubular portion supported in a state of being at least partly embedded in the fixing piece, and a maximum width of the rotation preventing protrusion may be greater than a minimum distance between the screw insertion tubular portion and the protector main body.

Since the rotation preventing protrusion is located farther from the protector main body than the screw insertion portion is, the rotation preventing protrusion can be made thicker (i.e. wider). By setting the maximum width of the rotation preventing protrusion greater than the minimum distance between the screw insertion tubular portion and the protector main body, it is possible to prevent rotation more reliably.

### Details of Embodiments of the Present Disclosure

Specific examples of a protector according to the present disclosure will be described below with reference to the drawings. The present disclosure is not limited to these examples, but is defined by the claims and intended to include all modifications within the meaning and scope equivalent to the claims.

### Embodiment

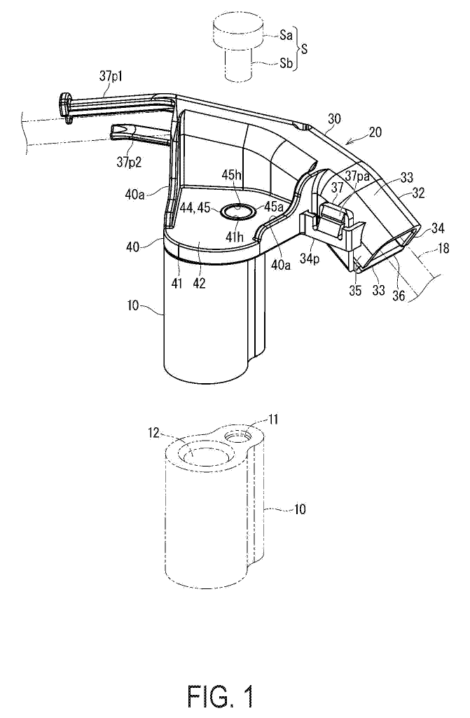

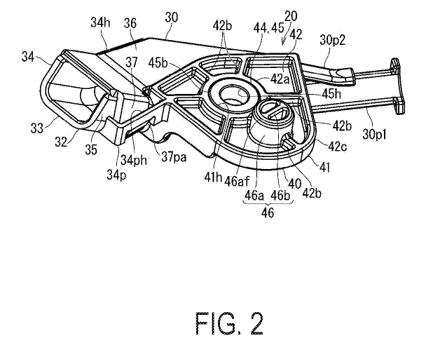

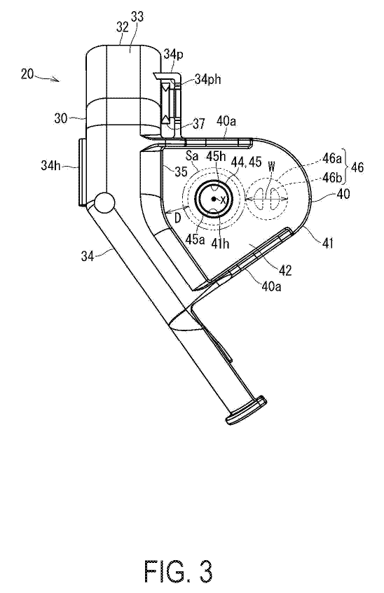

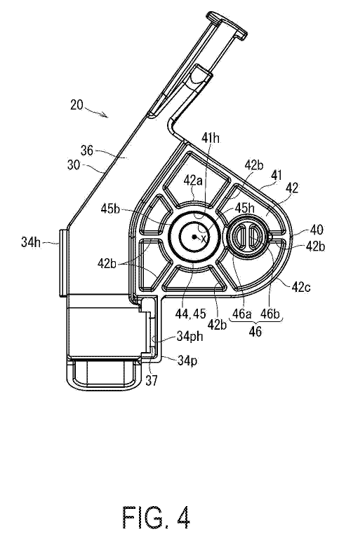

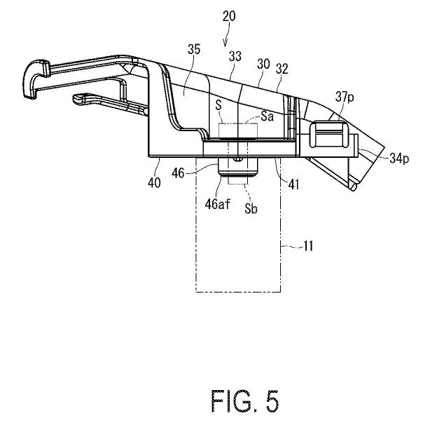

A protector according to an embodiment will be described below. FIGS. 1 and 2 are perspective views showing a protector 20. In FIG. 1, a fixing object 10 for the protector 20 is shown. The fixing object 10 to which the protector 20 has been fixed is indicated by solid lines, and the fixing object 10 before the protector 20 is fixed is indicated by long dashed double-short dashed lines. FIG. 3 is a plan view showing the protector 20. In FIG. 3, a screw insertion portion 44 and a rotation preventing protrusion 46 seen from the bottom side are indicated by broken lines. FIG. 4 is a bottom view showing the protector 20. FIG. 5 is a side view showing the protector 20.

The protector 20 is fixed to the fixing object 10. The fixing object 10 is, for example, a part of the body of a vehicle. As an example, the fixing object 10 is a projecting base that projects from the body. A screw hole 11 and a rotation preventing hole 12 are formed in the fixing object 10. The screw hole 11 and the rotation preventing hole 12 may be blind holes or through holes.

The protector 20 includes a protector main body 30 and a screw fixing portion 40 (screw fixing body). For example, the protector 20 may be integrally molded by filling a mold with molten resin.

The protector main body 30 holds a wiring member 18 (wire). The wiring member 18 is, for example, formed by bundling a plurality of electric wires. The wiring member 18 may be part of a wire harness in which a plurality of electric wires are bundled while being branched.

The protector main body 30 may be formed into a shape capable of accommodating the wiring member 18. For example, the protector main body 30 may have a tube shape or a trough shape. In this embodiment, the protector main body 30 has a tube shape.

The protector main body 30 may have a shape that bends at an intermediate part, or a shape that extends straight. In this embodiment, the protector main body 30 has a shape that bends at an intermediate part. The protector main body 30 may form a single wiring space without branching, or form a wiring space that branches at an intermediate part. In this embodiment, the protector main body 30 forms a single wiring space without branching.

More specifically, the protector main body 30 includes an accommodating portion 32 and a lid portion 36.

The accommodating portion 32 includes a bottom portion 33 and a pair of side wall portions 34 and 35. An intermediate part of the bottom portion 33 in the longitudinal direction is bent in the width direction. The pair of side wall portions 34 and 35 rise from both side edges of the bottom portion 33. This forms the accommodating portion 32 that is U-shaped in cross section and is bent at the intermediate part.

The lid portion 36 is supported so as to be openable and closable via a hinge 34h at a tip edge of one side wall portion 34. The one side wall portion 34 is located on the outer side of the bending protector main body 30 (i.e., the opposite side to the side to which the protector main body 30 bends).

A locking piece 37p protrudes from the tip of the lid portion 36. A receiving portion 34p protrudes from the other side wall portion 35. The other side wall portion 35 is located on the inner side of the bending protector main body 30 (i.e., the side to which the protector main body 30 bends). A retaining protrusion 37pa is formed on the outward facing surface of the tip portion of the locking piece 37p. A locking hole 34ph into which the locking piece 37p is insertable is formed in the receiving portion 34p.

In a state where the lid portion 36 closes the opening of the accommodating portion 32 opposite to the bottom portion 33, the locking piece 37p is inserted into the locking hole 34ph. In this state, the retaining protrusion 37pa passes beyond the locking hole 34ph and is retained in the receiving portion 34p so as to prevent disengagement. Thus, the lid portion 36 is maintained in a closed state.

The protector main body 30 is open to the outside at both ends in its longitudinal direction. When an intermediate portion in the longitudinal direction of the wiring member 18 is accommodated in the protector main body 30, the wiring member 18 is held along a predetermined path corresponding to the shape of the protector main body 30. The wiring member 18 extends outward from the openings at both ends of the protector main body 30 and is drawn toward electrical components to be connected.

A wiring fixing piece 30p1 and a wiring pressing piece 30p2 for fixing the wiring member 18 may extend outward from an end of the protector main body 30. The wiring fixing piece 30p1 may be a part where the wiring member 18 and a binding member such as adhesive tape are bound together. The wiring pressing piece 30p2 may be an elastic piece that presses the wiring member 18 toward the wiring fixing piece 30p1.

The screw fixing portion 40 protrudes from the protector main body 30. The screw fixing portion 40 includes a screw insertion portion 44 (screw insertion) and a rotation preventing protrusion 46 as a rotation preventing portion. A screw S is inserted into the screw insertion portion 44. The rotation preventing protrusion 46 is located away from the central axis X of the screw insertion portion 44.

The screw fixing portion 40 is fixed to the fixing object 10 by the screw S inserted into the screw insertion portion 44. As a result, the protector main body 30 is fixed to the fixing object 10 so as not to separate from the fixing object 10. Moreover, the rotation preventing protrusion 46 contacts the fixing object 10 to restrict rotation of the screw fixing portion 40 around the screw S. The protector 20 is thus restricted from rotating around the screw S. In other words, the protector 20 is prevented from rotation so as to maintain a predetermined orientation relative to the fixing object.

Hence, as a result of a single screw fixing portion 40 being fixed to the fixing object 10 by a single screw S, the protector 20 is fixed to the fixing object 10 in a state of being prevented from rotation.

### Screw Fixing Portion

The screw fixing portion will be described in more detail below.

The screw fixing portion 40 includes a fixing piece 41. The fixing piece 41 is a plate-shaped portion extending (i.e. protruding) from the other side wall portion 35. The fixing piece 41 may extend from a part of the side wall portion 35 in its extending direction. In this embodiment, the fixing piece 41 extends from a region of the side wall portion 35 including a bending part of the protector main body 30.

The fixing piece 41 may have any orientation relative to the protector main body 30. In this embodiment, the fixing piece 41 extends in an orientation along the extension plane of the bottom portion 33. Both side edges of the proximal end portion of the fixing piece 41 may be connected to the side wall portion 35 via auxiliary plate portions 40a.

The fixing piece 41 may have any shape. In this embodiment, the fixing piece 41 gradually narrows in width from the proximal end toward the distal end. The distal end of the fixing piece 41 has a partial disk shape.

The screw insertion portion 44 is located at an intermediate position of the fixing piece 41. The intermediate position of the fixing piece 41 is a position inside the peripheral edge of the fixing piece 41.

The screw insertion portion 44 may include, for example, a screw insertion tubular portion 45 (screw insertion tube) through which a screw shaft portion Sb of the screw S is insertable. The screw insertion tubular portion 45 may be a component called a collar. The screw insertion tubular portion 45 may be formed of a material harder than the resin forming the fixing piece 41. For example, the screw insertion tubular portion 45 may be a metal tube.

The screw insertion tubular portion 45 is supported in a state of being at least partly embedded in the fixing piece 41.

For example, a through hole 45h having a constant inner diameter is formed in the screw insertion tubular portion 45. The outer periphery of the screw insertion tubular portion 45 is formed such that an annular flange portion 45b extends from one end of a body portion 45a having a constant outer diameter.

A mounting hole 41h into which the screw insertion tubular portion 45 is insertable is formed in an intermediate portion of the fixing piece 41. The mounting hole 41h has a shape corresponding to the outer peripheral shape of the screw insertion tubular portion 45.

For example, the fixing piece 41 includes a plate portion 42, an annular protrusion 42a, and rib portions 42b (ribs). The plate portion 42 is, for example, a plate-shaped portion having a constant thickness. The annular protrusion 42a protrudes from the bottom surface side of the plate portion 42. The mounting hole 41h extending through the plate portion 42 in the thickness direction is formed in the annular protrusion 42a.

The mounting hole 41h extends to a size capable of accommodating the flange portion 45b on the fixing object 10 side and to a size capable of accommodating the body portion 45a on the side opposite to the fixing object 10 side, with an annular step portion facing the bottom interposed therebetween.

The screw insertion tubular portion 45 is mounted in the mounting hole 41h in a state where the flange portion 45b contacts the annular step portion. For example, the screw insertion tubular portion 45 may be press-fitted into the mounting hole 41h. The protector 20 including the fixing piece 41 may be molded from resin with the screw insertion portion 44 as an insert component. In this embodiment, the screw insertion tubular portion 45 is supported by the fixing piece 41 in a state where the entire outer peripheral surface of the screw insertion tubular portion 45 is embedded in the fixing piece 41.

A plurality of rib portions 42b extend radially around the central axis X of the screw insertion portion 44. In other words, the plurality of rib portions 42b extend in the radial direction of an imaginary circle centered on the central axis X.

A surrounding rib portion 42c protrudes from a part of the peripheral edge of the plate portion 42 not connected to the side wall portion 35. The plurality of rib portions 42b extend so as to connect to either the side wall portion 35 or the surrounding rib portion 42c.

The rotation preventing protrusion 46 protrudes from the fixing piece 41. The rotation preventing protrusion 46 protrudes more than the plate portion 42, and protrudes more than the annular protrusion 42a, the rib portions 42b, and the surrounding rib portion 42c.

The position of the rotation preventing protrusion 46 is away from the central axis X of the screw insertion portion 44. In this embodiment, the rotation preventing protrusion 46 is located farther from the protector main body 30 than the screw insertion portion 44 is. In other words, the rotation preventing protrusion 46 is located on the side of the screw insertion portion 44 opposite to the protector main body 30. It may be understood that the screw insertion portion 44 is located between the rotation preventing protrusion 46 and the protector main body 30.

The position of the rotation preventing protrusion 46 is not limited to the above example, and may be any position. The rotation preventing protrusion 46 may be located on the protector main body 30 side relative to the screw insertion portion 44.

At least one of the plurality of rib portions 42b extends so as to pass through the rotation preventing protrusion 46. For example, among the plurality of rib portions 42b, a rib portion 42b extending toward the distal end of the plate portion 42 on the side opposite to the side wall portion 35 extends so as to pass through the rotation preventing protrusion 46. In this embodiment, the thickness (i.e. width) of the rotation preventing protrusion 46 is greater than the width of the rib portion 42b. Therefore, the rotation preventing protrusion 46 protrudes beyond both sides of the rib portion 42b.

The rotation preventing protrusion 46 may have any outer shape. The outer shape of the rotation preventing protrusion 46 may be a cylindrical surface shape or a prismatic surface shape. In this embodiment, the outer shape of the rotation preventing protrusion 46 is a cylindrical surface shape.

The rotation preventing protrusion 46 may have any thickness (width). The maximum width W (the diameter in this example) of the rotation preventing protrusion 46 may be greater than the minimum distance D between the screw insertion tubular portion 45 and the protector main body 30. The rotation preventing protrusion 46 is located farther from the protector main body 30 than the screw insertion portion 44 is. Therefore, the rotation preventing protrusion 46 can be easily increased in thickness without being constrained by the distance between the screw insertion tubular portion 45 and the protector main body 30, so that the maximum width W of the rotation preventing protrusion 46 can be made greater than the minimum distance D.

The amount by which the rotation preventing protrusion 46 protrudes is such that, in a state where the screw fixing portion 40 is in contact with the fixing object 10, the rotation preventing protrusion 46 can fit into the rotation preventing hole 12. For example, the protrusion amount of the rotation preventing protrusion 46 relative to the rib portion 42b may be less than or equal to 1/2 of the maximum width W (diameter) of the rotation preventing protrusion 46. The protrusion amount may be greater than or equal to 1/3 of the maximum width W (diameter). With such a protrusion amount, the rotation preventing protrusion 46 can be easily inserted into the rotation preventing hole 12 while ensuring the rotation preventing function.

The rotation preventing protrusion 46 may be a hollow part or a solid part with the inside filled. In this embodiment, the rotation preventing protrusion 46 includes a tubular portion 46a (tube) and a partition portion 46b (partition). The tubular portion 46a protrudes from the plate portion 42. One of the rib portions 42b extends in the diameter direction of the tubular portion 46a.

The tubular portion 46a is open on the fixing object 10 side, and is closed on the opposite side by the plate portion 42.

The partition portion 46b partitions the inside of the tubular portion 46a. For example, the partition portion 46b extends in the diameter direction so as to divide the tubular portion 46a in half. The partition portion 46b may extend, for example, in a direction orthogonal to the rib portion 42b passing through the tubular portion 46a.

The use of the above-described hollow structure for the rotation preventing protrusion 46 can reduce the amount of resin material for forming the screw fixing portion 40. Moreover, by reducing the wall thickness of the screw fixing portion 40, it is possible to prevent resin sink marks of the screw fixing portion 40. In addition, as a result of the partition portion 46b passing through the inside of the tubular portion 46a, the rotation preventing protrusion 46 can be made robust while having a hollow structure.

The rotation preventing protrusion 46 may include a guide surface 46af that gradually tapers toward the tip. For example, the tip portion of the tubular portion 46a may include a tapered guide surface 46af that gradually decreases in diameter toward the tip. This facilitates insertion of the rotation preventing protrusion 46 into the rotation preventing hole 12.

The protector 20 is fixed to the fixing object 10 in the following manner. The protector 20 in which the wiring member 18 is accommodated in the protector main body 30 is prepared. While the rotation preventing protrusion 46 is being inserted into the rotation preventing hole 12, the screw fixing portion 40 is placed on the fixing object 10. In this state, the rotation preventing protrusion 46 is located on the side of the screw S opposite to the protector main body 30. Therefore, the rotation preventing protrusion 46 is easily visible from the side opposite to the protector main body 30. The rotation preventing protrusion 46 can be inserted into the rotation preventing hole 12 while checking the tip position of the rotation preventing protrusion 46. The operation of inserting the rotation preventing protrusion 46 is thus easy.

The screw S is inserted through the through hole 45h of the screw insertion portion 44 and screwed into the screw hole 11. Then, as the fixing piece 41 is clamped between the screw head Sa and the fixing object 10, the protector 20 is fixed to the fixing object 10. In this state, since the rotation preventing protrusion 46 is inserted into the rotation preventing hole 12, even if the protector 20 tries to rotate around the screw S, the rotational moment is received by the fitting structure between the rotation preventing protrusion 46 and the rotation preventing hole 12, and rotation of the protector 20 is restricted.

### Effects, etc.

In the protector 20 having the above-described structure, the screw fixing portion 40 includes the screw insertion portion 44 and the rotation preventing protrusion 46 located away from the center of the screw insertion portion 44, and the rotation preventing protrusion 46 contacts the fixing object 10 so as to restrict rotation of the screw fixing portion 40 around the screw S. Rotation of the protector 20 around the screw S is thus restricted. As a result, the path of the wiring member 18 and the position of the protector 20 can be regulated with high accuracy.

Since rotation of the protector 20 can be restricted with only one screw fixing portion 40, it is unnecessary to fix the protector to the fixing object at multiple locations in order to prevent rotation. This simplifies the shape of the protector 20 and reduces costs.

In addition, it is unnecessary to set multiple fixing locations on the fixing object 10, so that the fixed region of the fixing object 10 can be reduced.

Moreover, since the rotation preventing portion is the rotation preventing protrusion 46, rotation of the protector 20 can be prevented by forming, in the fixing object 10, the rotation preventing hole 12 into which the rotation preventing protrusion 46 is fitted. For example, if the fixing object 10 is a metal member, it is easier to form a recessed shape than a protruding shape. If the protector 20 is made of resin or the like, forming a protruding shape is easy. Thus, the structure for preventing rotation can be obtained easily.

Moreover, as a result of the rotation preventing protrusion 46 including the tubular portion 46a and the partition portion 46b, the amount of material for forming the screw fixing portion 40 can be reduced, and resin sink marks and the like can be suppressed. In addition, with the partition portion 46b, the rotation preventing protrusion 46 can be made robust while having a hollow structure. The robust rotation preventing protrusion 46 prevents rotation more reliably.

Moreover, since the fixing piece 41 includes the rib portions 42b that extend radially, the screw insertion portion 44 is securely supported in the fixing piece 41. In addition, since at least one of the plurality of rib portions 42b extends so as to pass through the rotation preventing protrusion 46, the rotation preventing protrusion 46 is also securely supported. As a result, the rotation preventing protrusion 46 prevents rotation more reliably.

Moreover, since the rotation preventing protrusion 46 includes the guide surface 46af, the rotation preventing protrusion 46 can be easily fitted into the rotation preventing hole 12 using the guide surface 46af.

Moreover, since the rotation preventing protrusion 46 is located farther from the protector main body 30 than the screw insertion portion 44 is, the rotation preventing protrusion 46 can be easily checked without being obstructed by the protector main body 30. Therefore, the rotation preventing protrusion 46 can be easily inserted into the rotation preventing hole 12 of the fixing object 10 so that rotation can be restricted.

Moreover, the position and shape of the rotation preventing protrusion 46 can be set while suppressing the influence of the protector main body 30. For example, the rotation preventing protrusion 46 can be easily located farther from the screw insertion portion 44. When the rotation preventing protrusion 46 is farther from the screw insertion portion 44, the rotational moment of rotating the protector 20 can be received more effectively.

Moreover, for example, the maximum width W of the rotation preventing protrusion 46 can be set greater than the minimum distance D between the screw insertion tubular portion 45 and the protector main body 30. This prevents rotation more reliably.

### Modifications

In the above embodiment, an example in which the screw insertion portion 44 is a hole through which the screw S is inserted has been described. Alternatively, the screw insertion portion may be a screw hole into which a screw is screwed. In this case, a screw protruding from the fixing object may be screwed into the screw insertion portion as a screw hole.

In the above embodiment, an example in which the rotation preventing portion is the rotation preventing protrusion 46 has been described. Alternatively, the rotation preventing portion may be a rotation preventing recess for preventing rotation. The rotation preventing recess may be a blind (bottomed) recess or a through hole. In this case, a rotation preventing protrusion protruding from the fixing object 10 may be fitted into the rotation preventing recess to restrict rotation of the protector.

The configurations described in the above embodiments and modifications may be combined as appropriate as long as they are not mutually contradictory.

What is claimed is:

1. A protector configured to be fixed to a fixing object by a screw, the protector comprising:
a protector main body that is configured to hold a wire; and
a screw fixing body that protrudes from the protector main body, wherein:
the screw fixing body includes a screw insertion that is configured for the screw is to be inserted, and a rotation preventing portion located away from a center of the screw insertion, and
the rotation preventing portion is configured to contact the fixing object to restrict rotation of the screw fixing body around the screw.

2. The protector according to claim 1, wherein the screw fixing body includes a fixing piece protruding from the protector main body, and the rotation preventing portion is a rotation preventing protrusion protruding from the fixing piece.

3. The protector according to claim 2, wherein the rotation preventing protrusion includes a tube and a partition partitioning an inside of the tube.

4. The protector according to claim 2, wherein the screw insertion is located at an intermediate position of the fixing piece, the fixing piece includes a plurality of ribs extending radially around a central axis of the screw insertion, and at least one rib of the plurality of ribs extends to pass through the rotation preventing protrusion.

5. The protector according to claim 2, wherein the rotation preventing protrusion includes a guide surface that gradually tapers toward a tip.

6. The protector according to claim 2, wherein the rotation preventing protrusion is located farther from the protector main body than the screw insertion.

7. The protector according to claim 6, wherein the screw insertion includes a screw insertion tube supported in a state of being at least partly embedded in the fixing piece, and a maximum width of the rotation preventing protrusion is greater than a minimum distance between the screw insertion tube and the protector main body.
